(19) United States
(12) Patent Application Publication
(10) Pub. No.: US 2023/0127781 A1
(43) Pub. Date: Apr. 27, 2023

(54) PRODUCTION METHOD FOR SEMICONDUCTOR MEMORY DEVICE

(71) Applicant: Unisantis Electronics Singapore Pte. Ltd., Singapore (SG)

(72) Inventors: Riichiro SHIROTA, Hsinchu City (TW); Nozomu HARADA, Chiyoda-ku, Tokyo (JP); Koji SAKUI, Chiyoda-ku, Tokyo (JP)

(21) Appl. No.: 17/971,789

(22) Filed: Oct. 24, 2022

(30) Foreign Application Priority Data
Oct. 25, 2021 (JP) PCT/JP2021/039319

(51) Int. Cl. H01L 27/108; H01L 29/78

(52) U.S. Cl. CPC H01L 27/10844; H01L 27/10802; H01L 29/7841

(57) ABSTRACT

A dynamic flash memory cell is formed by: stacking a first insulating layer, a first material layer, a second insulating layer, a second material layer, a third insulating layer, and a third material layer on a first impurity layer on a P-layer substrate; making a first hole that extends through the insulating layers and the material layers formed on the P-layer substrate; forming a semiconductor pillar by filling the first hole; making a second hole and a third hole by removing the first material layer and the second material layer; forming a first gate insulating layer and a second gate insulating layer by oxidizing a surface layer of the semiconductor pillar exposed inside the second hole and inside the third hole; and forming a first gate conductor layer and a second gate conductor layer by filling the second hole and the third hole.

### CROSS REFERENCES TO RELATED APPLICATIONS

This application claims priority to PCT/JP2021/039319, filed Oct. 25, 2021, the entire content of which is incorporated herein by reference.

### BACKGROUND OF THE INVENTION

### 1. Field of the Invention

The present invention relates to a production method for a semiconductor memory device.

### 2. Description of the Related Art

Recently, there has been a demand for highly integrated and high-performance memory elements in the development of LSI (Large Scale Integration) technology.

Typical planar MOS transistors include a channel that extends in a horizontal direction along the upper surface of the semiconductor substrate. In contrast, SGTs include a channel that extends in a direction perpendicular to the upper surface of the semiconductor substrate (see, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Accordingly, the density of semiconductor devices can be made higher with SGTs than with planar MOS transistors. Such SGTs can be used as selection transistors to implement highly integrated memories, such as a DRAM (Dynamic Random Access Memory, see, for example, H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) to which a capacitor is connected, a PCM (Phase Change Memory, see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)) to which a resistance change element is connected, an RRAM (Resistive Random Access Memory, see, for example, T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)), and an MRAM (Magneto-resistive Random Access Memory, see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) that changes the resistance by changing the orientation of a magnetic spin with a current. Further, there exists, for example, a DRAM memory cell (see M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)) constituted by a single MOS transistor and including no capacitor. The present application relates to a dynamic flash memory that can be constituted only by a MOS transistor and that includes no resistance change element or capacitor.

FIGS. 8A to 8D illustrate a write operation of a DRAM memory cell constituted by a single MOS transistor and including no capacitor described above, FIGS. 9A and 9B illustrate a problem in the operation, and FIGS. 10A to 10C illustrate a read operation.

FIGS. 8A to 8D illustrate a write operation of a DRAM memory cell. FIG. 8A illustrates a “1” write state. Here, the memory cell is formed on an SOI substrate 100, is constituted by a source N⁺ layer 103 (hereinafter, a semiconductor region that contains a donor impurity in high concentrations is referred to as “N⁺ layer”) to which a source line SL is connected, a drain N⁺ layer 104 to which a bit line BL is connected, a gate conductor layer 105 to which a word line WL is connected, and a floating body 102 of a MOS transistor 110a, and includes no capacitor. The single MOS transistor 110a constitutes the DRAM memory cell. Directly under the floating body 102, a SiO₂ layer 101 of the SOI substrate is in contact with the floating body 102. To write “1” to the memory cell constituted by the single MOS transistor 110a, the MOS transistor 110a is operated in the saturation region. That is, a channel 107, for electrons, extending from the source N⁺ layer 103 has a pinch-off point 108 and does not reach the drain N⁺ layer 104 to which the bit line is connected. When a high voltage is applied to both the bit line BL connected to the drain N⁺ layer 104 and the word line WL connected to the gate conductor layer 105, and the MOS transistor 110a is operated at the gate voltage that is about one-half of the drain voltage, the electric field intensity becomes maximum at the pinch-off point 108 that is in the vicinity of the drain N⁺ layer 104. As a result, accelerated electrons that flow from the source N⁺ layer 103 toward the drain N⁺ layer 104 collide with the Si lattice, and with kinetic energy lost at the time of collision, electron-positive hole pairs are generated (impact ionization phenomenon). Most of the generated electrons (not illustrated) reach the drain N⁺ layer 104. Further, a very small proportion of the electrons that are very hot pass through a gate oxide film 109 and reach the gate conductor layer 105. Simultaneously, positive holes 106 are generated with which the floating body 102 is charged. In this case, the generated positive holes contribute to an increase in the majority carriers because the floating body 102 is P-type Si. When the floating body 102 is filled with the generated positive holes 106 and the voltage of the floating body 102 becomes higher than that of the source N⁺ layer 103 by Vb or more, further generated positive holes are discharged to the source N⁺ layer 103. Here, Vb is the built-in voltage of the PN junction between the source N⁺ layer 103 and the P-layer floating body 102 and is equal to about 0.7 V. FIG. 8B illustrates a state in which the floating body 102 is charged to saturation with the generated positive holes 106.

Now, a “0” write operation of a memory cell 110b will be described with reference to FIG. 8C. For the common selection word line WL, the memory cell 110a to which “1” is written and the memory cell 110b to which “0” is written are present at random. FIG. 8C illustrates a state of rewriting from the “1” write state to a “0” write state. To write “0”, the voltage of the bit line BL is set to a negative bias, and the PN junction between the drain N⁺ layer 104 and the P-layer floating body 102 is forward biased. As a result, the positive holes 106 in the floating body 102 generated in advance in the previous cycle flow into the drain N⁺ layer 104 that is connected to the bit line BL. When the write operation ends, the two memory cells are in a state in which the memory cell 110a (FIG. 8B) is filled with the generated positive holes 106, and from the memory cell 110b (FIG. 8C), the generated positive holes are discharged. The potential of the floating body 102 of the memory cell 110a filled with the positive holes 106 becomes higher than that of the floating body 102 in which generated positive holes are not present. Therefore, the threshold voltage for the memory cell 110a becomes lower than the threshold voltage for the memory cell 110b. This is illustrated in FIG. 8D.

Now, a problem in the operation of the memory cell constituted by the single MOS transistor will be described with reference to FIGS. 9A and 9B. As illustrated in FIG. 9A, the capacitance C_{FB} of the floating body 102 is equal to the sum of the capacitance C_{WL} between the gate to which the word line is connected and the floating body 102, the junction capacitance C_{SL} of the PN junction between the source N⁺ layer 103 to which the source line is connected and the floating body 102, and the junction capacitance C_{BL} of the PN junction between the drain N⁺ layer 104 to which the bit line is connected and the floating body 102 and is expressed as follows.

C_{FB}=C_{WL}+C_{BL}+C_{SL} (1)

Therefore, a change in the word line voltage V_{WL} at the time of writing affects the voltage of the floating body 102 that functions as a storage node (contact point) of the memory cell. This is illustrated in FIG. 9B. When the word line voltage V_{WL} rises from 0 V to V_{progWL} at the time of writing, the voltage V_{FB} of the floating body 102 rises from V_{FB1}, which is the voltage in the initial state before the word line voltage changes, to V_{FB2} due to capacitive coupling with the word line. The voltage change amount ΔV_{FB} is expressed as follows.

ΔV_{FB}=V_{FB2}−V_{FB1}=C_{WL}/(C_{WL}+C_{BL}+C_{SL})×V_{ProgWL} (2)

Here, C_{WL}/(C_{WL}+C_{BL}+C_{SL}) is expressed as follows.

β=C_{WL}/(C_{WL}+C_{BL}+C_{SL}) (3)

β is called a coupling ratio. In this memory cell, the contribution ratio of C_{WL} is large and, for example, C_{WL}:C_{BL}:C_{SL}=8:1:1 holds. This results in β=0.8. When the word line changes, for example, from 5 V at the time of writing to 0 V after the end of writing, the floating body 102 receives an amplitude noise of 5V×β=4 V due to capacitive coupling between the word line and the floating body 102. Accordingly, a sufficient margin is not provided to the potential difference between the “1” potential and the “0” potential of the floating body at the time of writing, which is a problem.

FIGS. 10A to 100 illustrate a read operation.

FIG. 10A illustrates a “1” write state and FIG. 10B illustrates a “0” write state. In actuality, however, even when Vb is set for the floating body 102 to write “1”, once the word line returns to 0 V at the end of writing, the floating body 102 is lowered to a negative bias. When “0” is written, the floating body 102 is lowered to a further negative bias, and it is difficult to provide a sufficiently large margin to the potential difference between “1” and “0” at the time of writing as illustrated in FIG. 10C. This small operation margin has been a major problem of this DRAM memory cell. In addition, a high density needs to be attained in the DRAM memory cell.

### SUMMARY OF THE INVENTION

In capacitor-less single-transistor DRAMs (gain cells) in an SGT-including memory device, capacitive coupling between the word line and the SGT body in a floating state is strong. When the potential of the word line is changed at the time of data reading or at the time of data writing, the change is directly transmitted to the SGT body as noise, which has been a problem. This causes a problem of erroneous reading or erroneous rewriting of storage data and makes it difficult to commercially introduce capacitor-less single-transistor DRAMs (gain cells). The above-described problems need to be addressed, and further, high-performance and high-density DRAM memory cells need to be attained.

To address the above-described problems, a production method for a semiconductor memory device according to an aspect of the present invention is

a production method for a semiconductor memory device, the semiconductor memory device performing a data retention operation of retaining, inside a semiconductor pillar, a group of positive holes or a group of electrons that are majority carriers in the semiconductor pillar and that are generated by an impact ionization phenomenon or a gate-induced drain leakage current, by controlling voltages applied to a first gate conductor layer, a second gate conductor layer, a first impurity layer, and a second impurity layer, and a data erase operation of discharging, from inside the semiconductor pillar, the group of positive holes or the group of electrons that are majority carriers in the semiconductor pillar by controlling the voltages applied to the first gate conductor layer, the second gate conductor layer, the first impurity layer, and the second impurity layer, the production method including:

stacking the first impurity layer, a first insulating layer, a first material layer, a second insulating layer, a second material layer, and a third material layer on a substrate from a bottom in a vertical direction;

making a first hole that has a bottom portion on a surface or inside the first impurity layer and that extends through the first insulating layer, the first material layer, the second insulating layer, the second material layer, and the third material layer;

forming the semiconductor pillar by filling the first hole;

making a second hole by removing the first material layer, and making a third hole by removing the second material layer;

forming a first gate insulating layer by oxidizing a surface layer of the semiconductor pillar exposed in the second hole, and forming a second gate insulating layer by oxidizing a surface layer of the semiconductor pillar exposed in the third hole;

forming the first gate conductor layer by filling the second hole so as to cover the first gate insulating layer, and forming the second gate conductor layer by filling the third hole so as to cover the second gate insulating layer; and

forming the second impurity layer connected to a top portion of the semiconductor pillar (first invention).

In the first invention described above, the production method further includes: forming one of the first impurity layer or the second impurity layer so as to be connected to a source line, and forming the other of the first impurity layer or the second impurity layer so as to be connected to a bit line (second invention).

In the first invention described above, the production method further includes: forming one of the first gate conductor layer or the second gate conductor layer so as to be connected to a word line, and forming the other of the first gate conductor layer or the second gate conductor layer so as to be connected to a plate line (third invention).

In the first invention described above, the production method further includes:

exposing the top portion of the semiconductor pillar by removing an upper portion of the third material layer, the third material layer being formed of two material layers including a lower layer that is an insulating layer, or by etching an upper portion of the third material layer, the third material layer being formed of an insulating material layer; and

forming a third impurity layer so as to cover the exposed top portion of the semiconductor pillar, in which

the third impurity layer functions as the second impurity layer (fourth invention).

In the third invention described above, the production method further includes:

forming a fourth impurity layer in the top portion of the semiconductor pillar, in which

the third impurity layer and the fourth impurity layer form the second impurity layer (fifth invention).

In the first invention described above, the first gate insulating layer and the second gate insulating layer are formed, and subsequently, a third gate insulating layer is formed on an inner wall of the second hole and on an inner wall of the third hole so as to cover the first gate insulating layer and the second gate insulating layer respectively (sixth invention).

In the first invention described above, the third material layer includes at least one insulating layer (seventh invention).

In the first invention described above, the production method further includes:

forming dummy semiconductor pillars in an outermost area of a block region, in plan view, in which semiconductor pillars each of which is the semiconductor pillar are disposed in two dimensions; and

etching and removing a portion of the first insulating layer, a portion of the first material layer, a portion of the second insulating layer, a portion of the second material layer, and a portion of the third material layer, the portions being outside the block region in plan view, prior to the making of the second hole by removing the first material layer and the making of the third hole by removing the second material layer (eighth invention).

In the first invention described above, the production method further includes: isolating one of the first gate conductor layer or the second gate conductor layer into a plurality of gate conductor layers in the vertical direction, or isolating each of the first gate conductor layer and the second gate conductor layer into a plurality gate conductor layers in the vertical direction (ninth invention).

### BRIEF DESCRIPTION OF THE DRAWINGS

FIG. 1 is a structural diagram of a semiconductor memory device according to a first embodiment;

FIGS. 2A, 2B, and 2C are diagrams for explaining a mechanism of an erase operation of the semiconductor memory device according to the first embodiment;

FIGS. 3A, 3B, and 3C are diagrams for explaining a mechanism of a write operation of the semiconductor memory device according to the first embodiment;

FIGS. 4AA, 4AB, and 4AC are diagrams for explaining a mechanism of a read operation of the semiconductor memory device according to the first embodiment;

FIGS. 4BA, 4BB, 4BC, and 4BD are diagrams for explaining the mechanism of the read operation of the semiconductor memory device according to the first embodiment;

FIGS. 5AA, 5AB, and 5AC are diagrams for explaining a production method for the semiconductor memory device according to the first embodiment;

FIGS. 5BA, 5BB, and 5BC are diagrams for explaining the production method for the semiconductor memory device according to the first embodiment;

FIGS. 5CA, 5CB, and 5CC are diagrams for explaining the production method for the semiconductor memory device according to the first embodiment;

FIGS. 5DA, 5DB, and 5DC are diagrams for explaining the production method for the semiconductor memory device according to the first embodiment;

FIGS. 5EA, 5EB, and 5EC are diagrams for explaining the production method for the semiconductor memory device according to the first embodiment;

FIGS. 5FA, 5FB, and 5FC are diagrams for explaining the production method for the semiconductor memory device according to the first embodiment;

FIGS. 5GA, 5GB, and 5GC are diagrams for explaining the production method for the semiconductor memory device according to the first embodiment;

FIGS. 5HA, 5HB, and 5HC are diagrams for explaining the production method for the semiconductor memory device according to the first embodiment;

FIGS. 5IA, 5IB, and 5IC are diagrams for explaining the production method for the semiconductor memory device according to the first embodiment;

FIGS. 5JA, 5JB, and 5JC are diagrams for explaining the production method for the semiconductor memory device according to the first embodiment;

FIGS. 5KA, 5KB, and 5KC are diagrams for explaining the production method for the semiconductor memory device according to the first embodiment;

FIGS. 5LA, 5LB, and 5LC are diagrams for explaining the production method for the semiconductor memory device according to the first embodiment;

FIGS. 5MA, 5MB, and 5MC are diagrams for explaining the production method for the semiconductor memory device according to the first embodiment;

FIGS. 6A, 6B, and 6C are diagrams for explaining a production method for the semiconductor memory device according to a second embodiment;

FIGS. 7AA, 7AB, and 7AC are diagrams for explaining a production method for the semiconductor memory device according to a third embodiment;

FIGS. 7BA, 7BB, and 7BC are diagrams for explaining the production method for the semiconductor memory device according to the third embodiment;

FIGS. 8A, 8B, 8C, and 8D are diagrams for explaining a write operation of a DRAM memory cell including no capacitor in the related art;

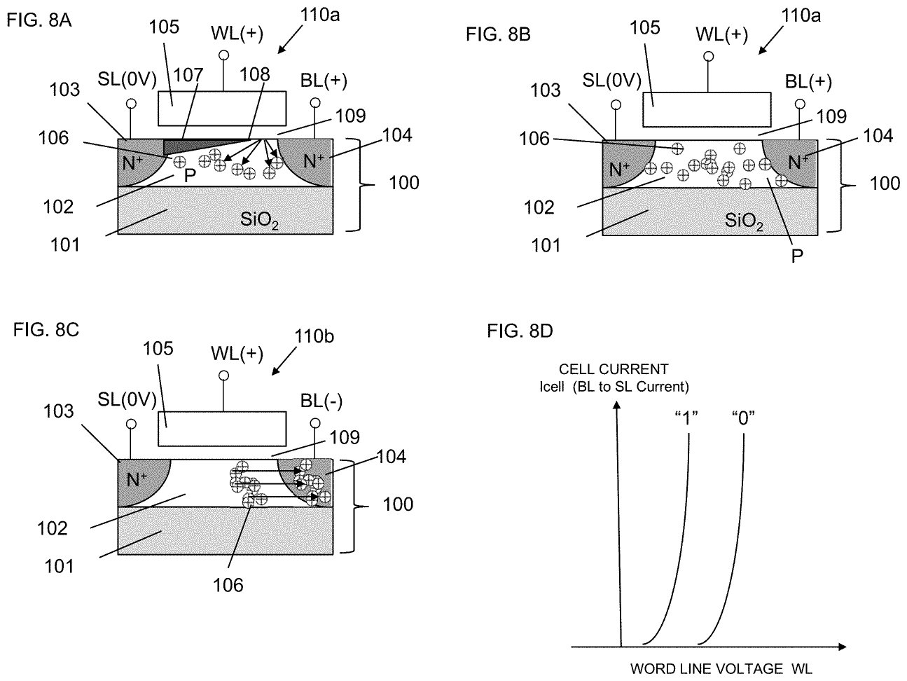

FIGS. 9A and 9B are diagrams for explaining a problem in the operation of the DRAM memory cell including no capacitor in the related art; and

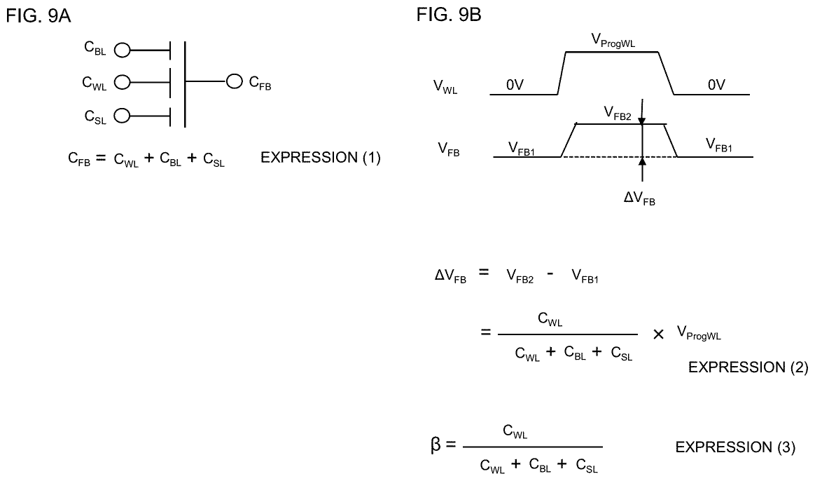

FIGS. 10A, 10B, and 10C are diagrams illustrating a read operation of the DRAM memory cell including no capacitor in the related art.

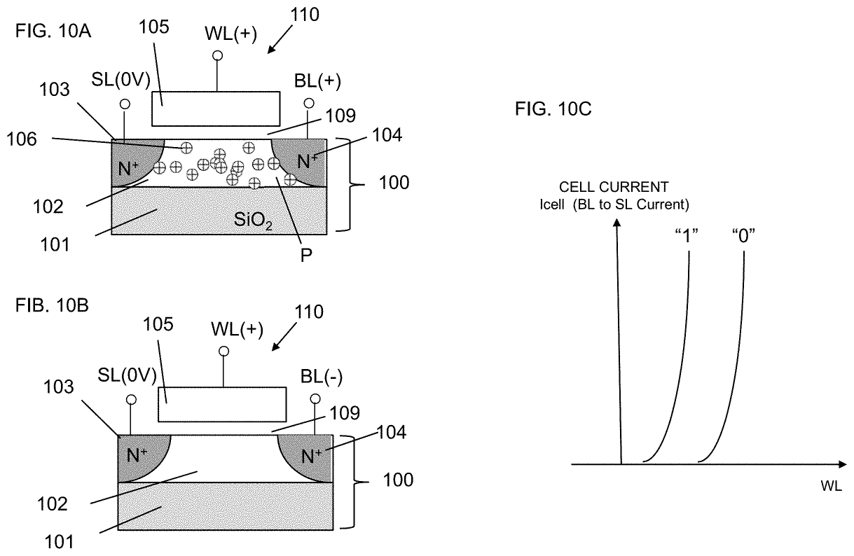

### DESCRIPTION OF THE PREFERRED EMBODIMENTS

Hereinafter, the structure, driving system, and production method for a semiconductor memory device (hereinafter called a dynamic flash memory) according to embodiments of the present invention will be described with reference to the drawings.

### First Embodiment

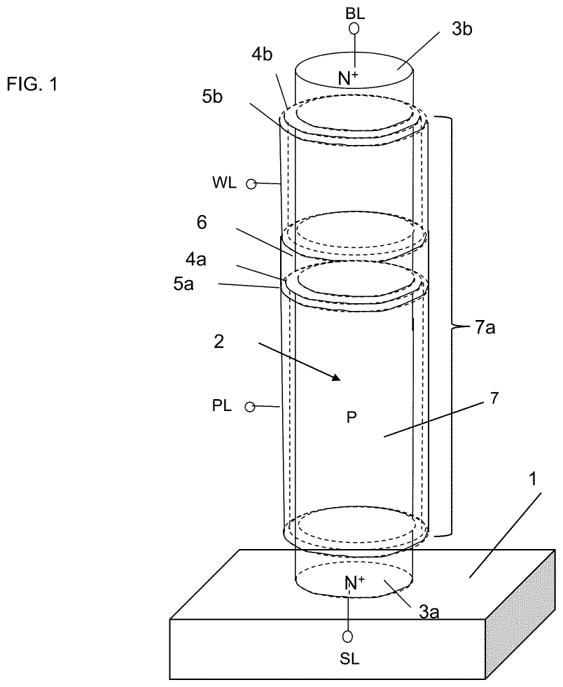

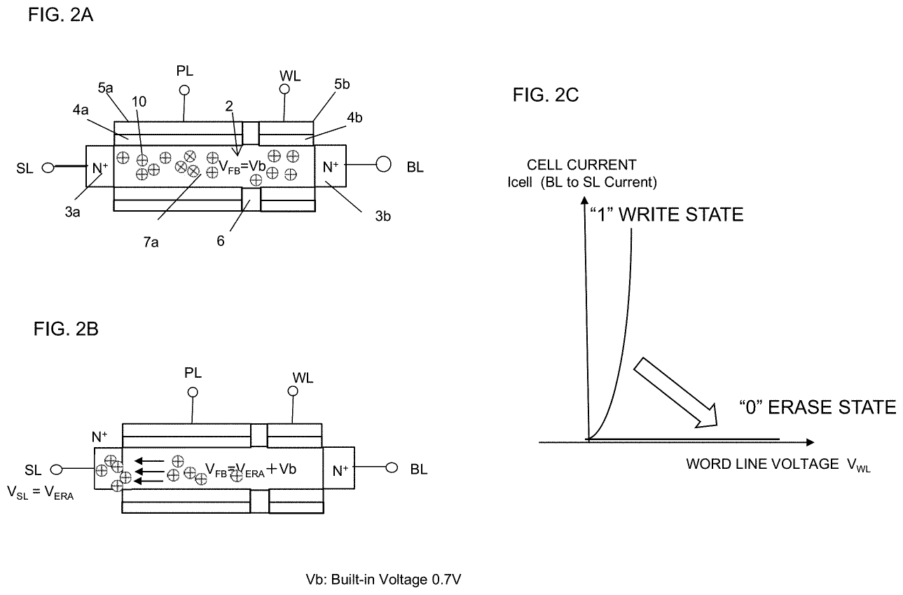

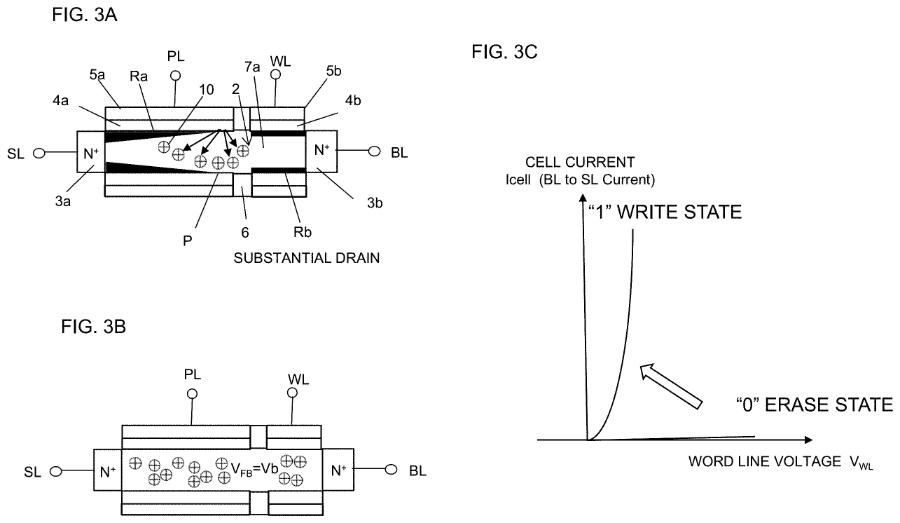

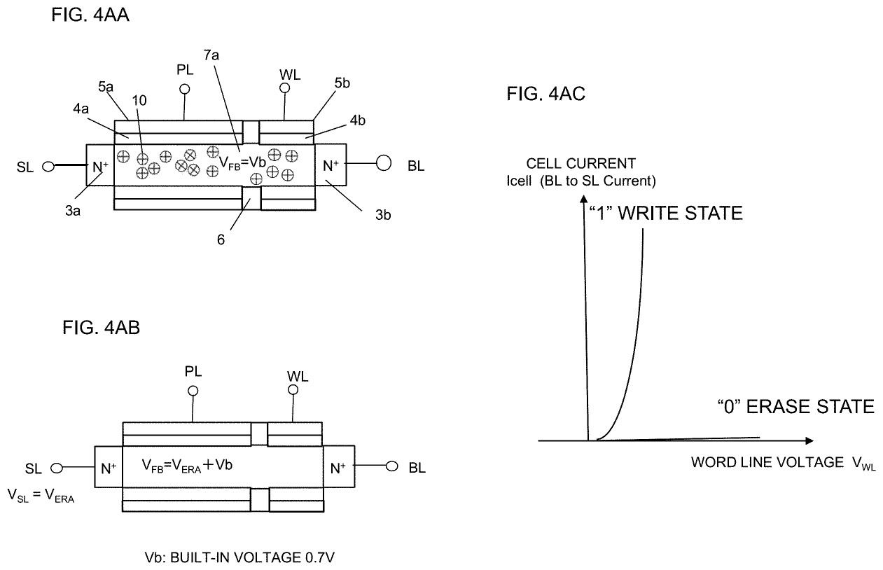

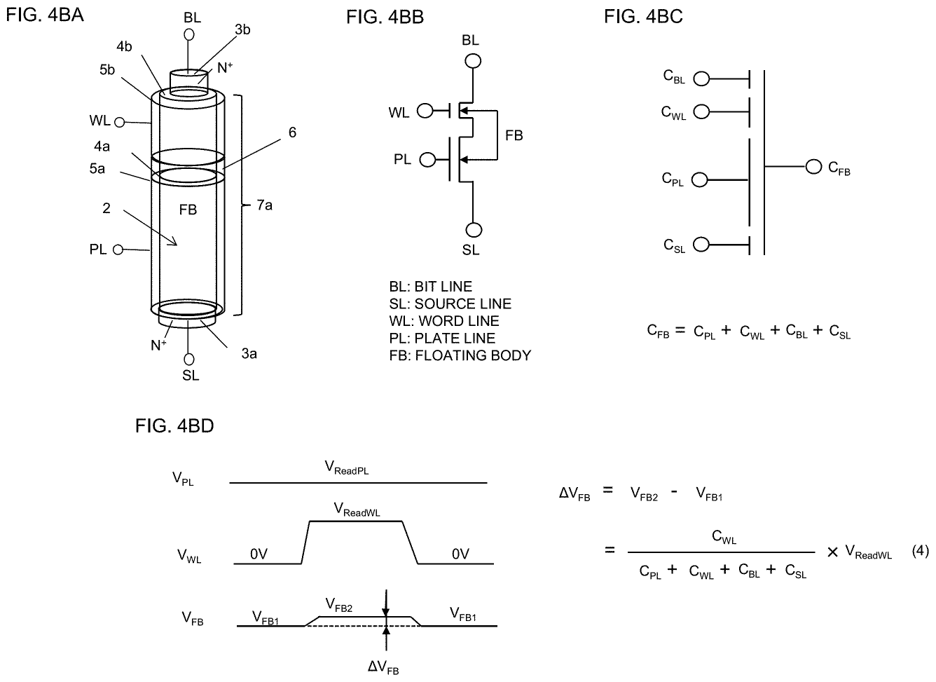

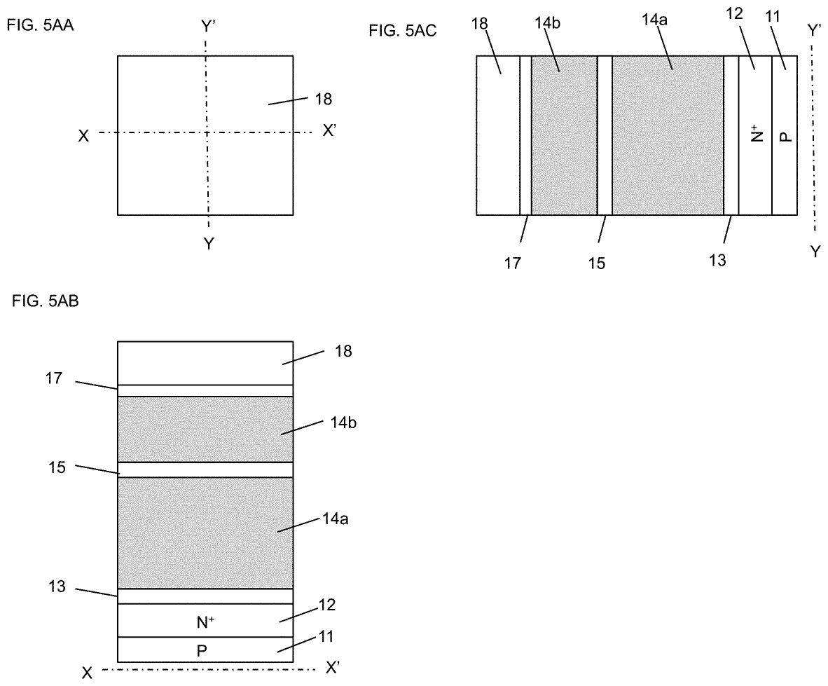

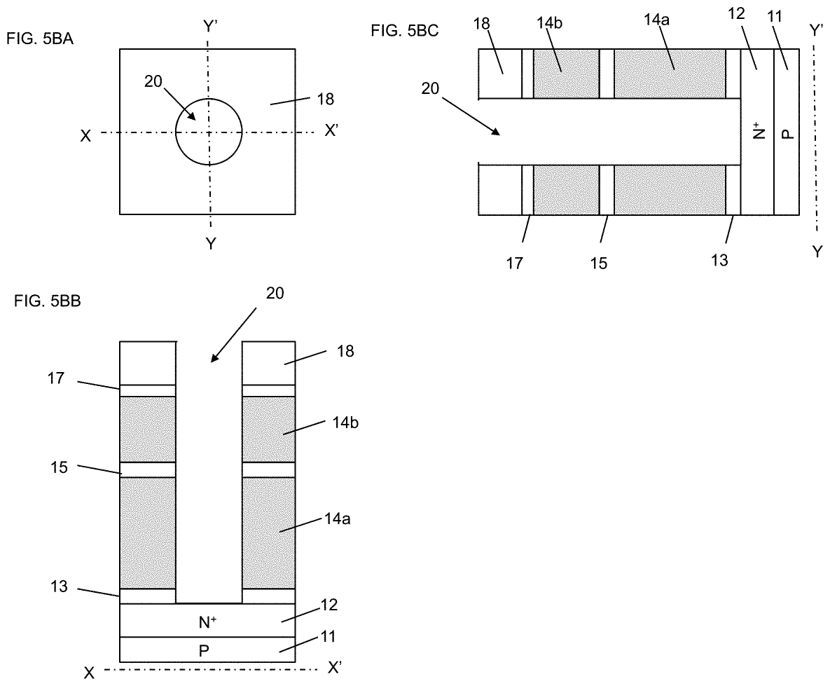

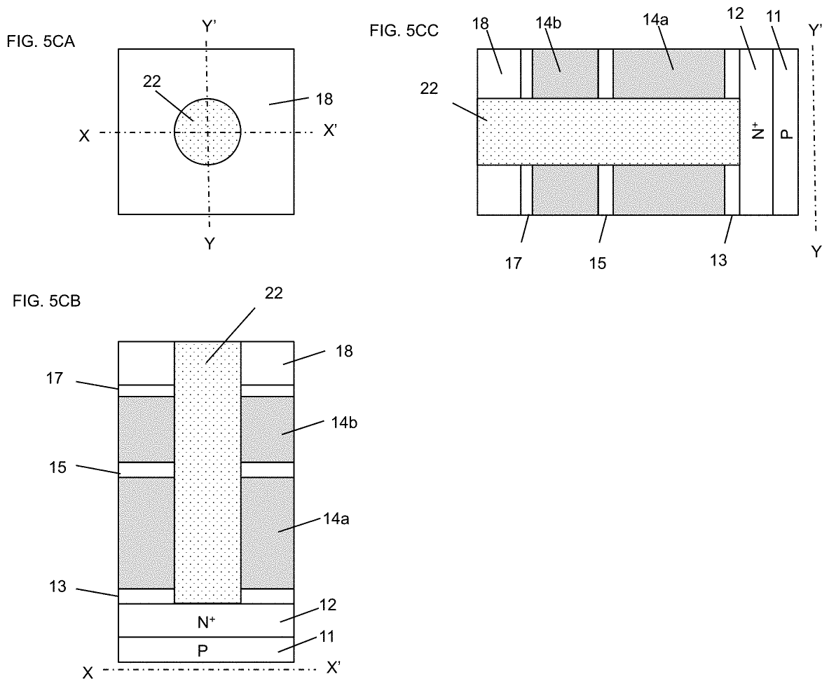

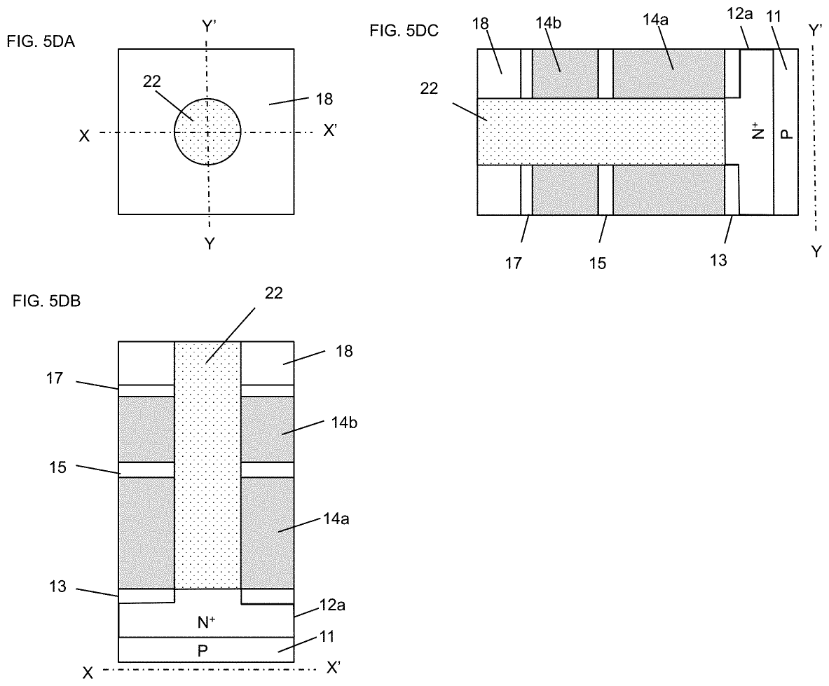

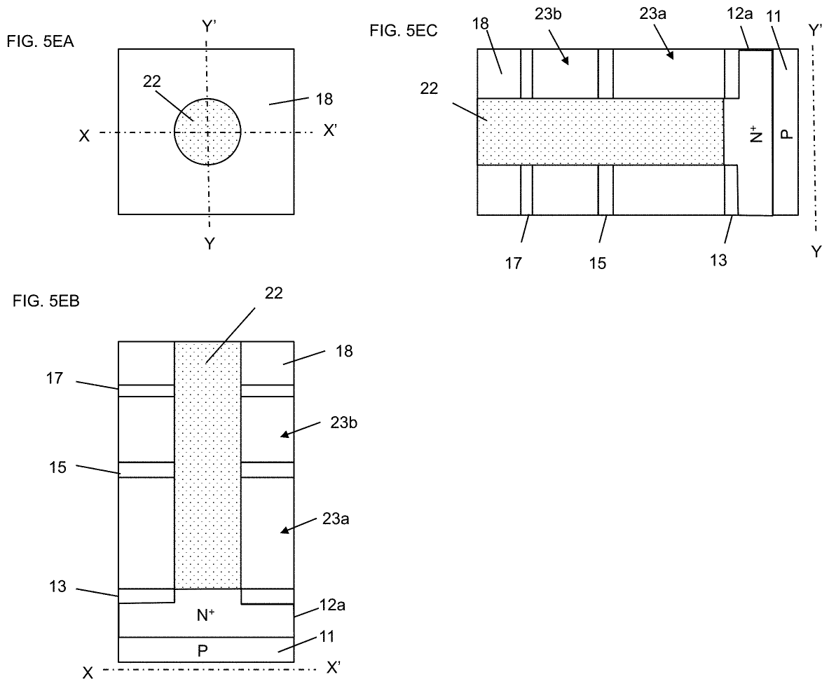

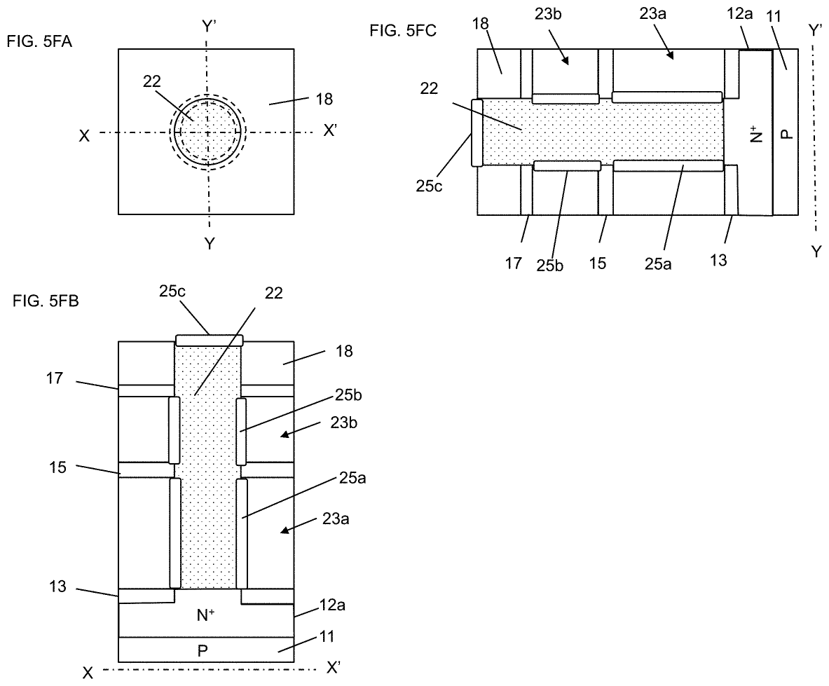

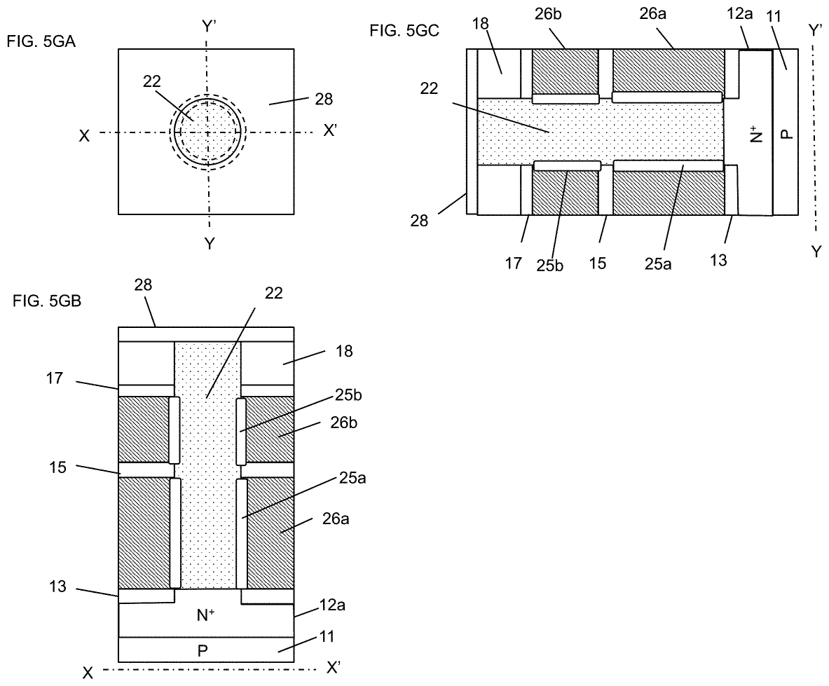

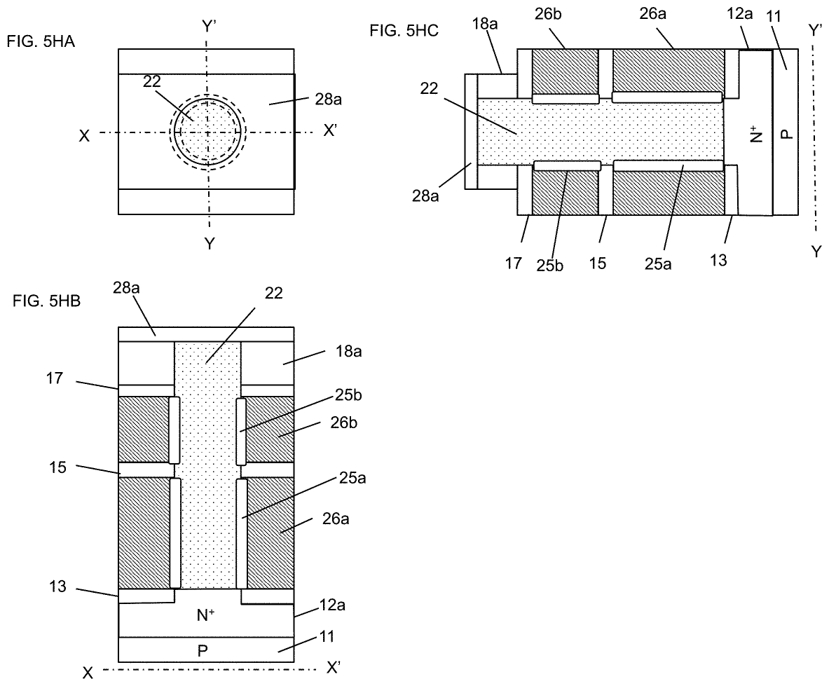

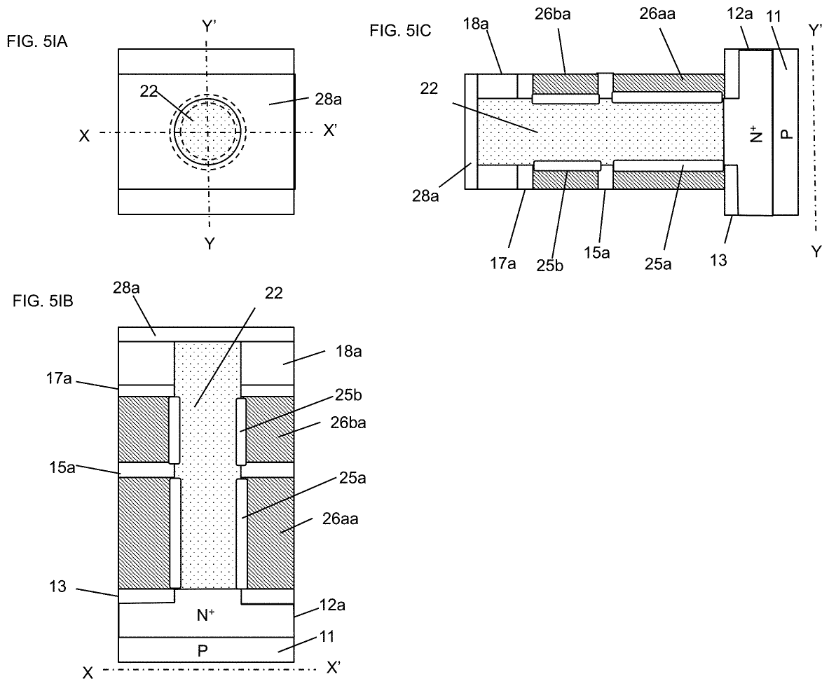

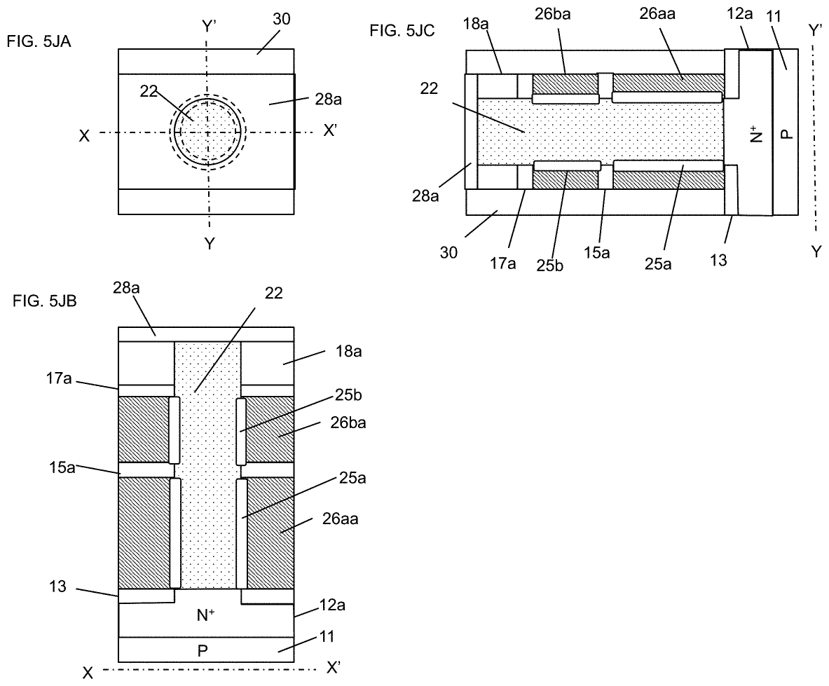

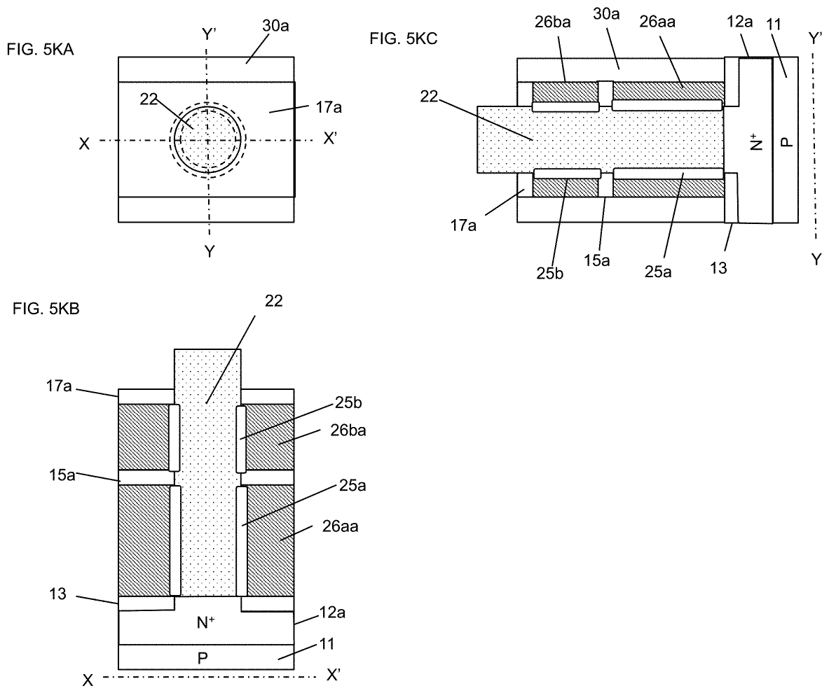

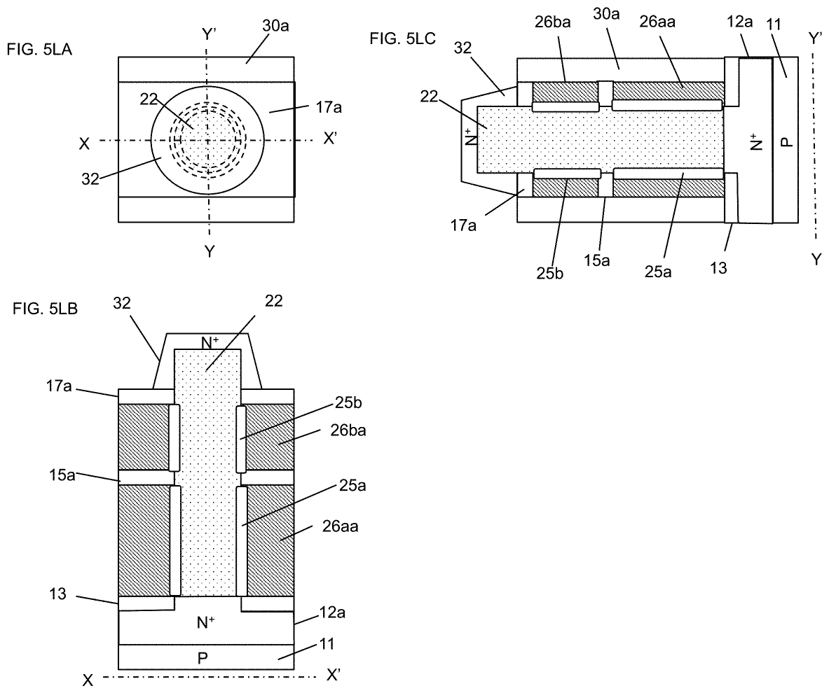

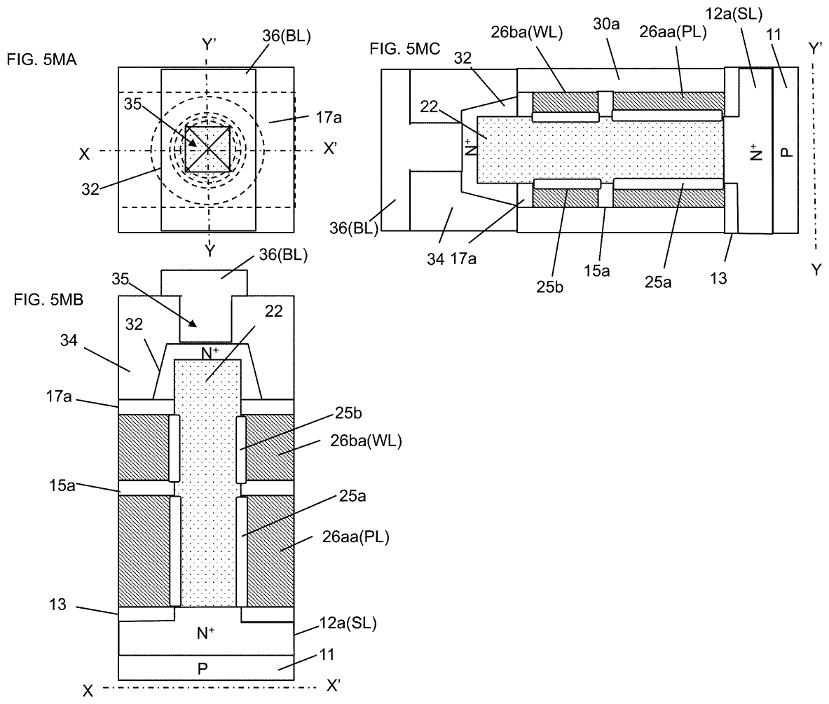

The structure, mechanisms of operations, and production method for a dynamic flash memory cell according to a first embodiment of the present invention will be described with reference to FIG. 1 to FIGS. 5AA to 5AC to FIGS. 5MA to 5MC. The structure of the dynamic flash memory cell will be described with reference to FIG. 1. A data erase mechanism will be described with reference to FIGS. 2A to 2C, a data write mechanism will be described with reference to FIGS. 3A to 3C, and a data read mechanism will be described with reference to FIGS. 4AA to 4AC and FIGS. 4BA to 4BD. The production method for the dynamic flash memory will be described with reference to FIGS. 5AA to 5AC to FIGS. 5MA to 5MC.

FIG. 1 illustrates the structure of the dynamic flash memory cell according to the first embodiment of the present invention. On a substrate 1 (which is an example of “substrate” in the claims), a silicon semiconductor pillar 2 (which is an example of “semiconductor pillar” in the claims) (the silicon semiconductor pillar is hereinafter referred to as “Si pillar”) is disposed. The Si pillar 2 is constituted by an N⁺ layer 3a (which is an example of “first impurity layer” in the claims), a semiconductor region 7 containing an acceptor impurity (the semiconductor region containing an acceptor impurity is hereinafter referred to as “P layer”), and an N⁺ layer 3b (which is an example of “second impurity layer” in the claims) from the bottom. The P layer 7 between the N⁺ layers 3a and 3b functions as a channel region 7a. A first gate insulating layer 4a (which is an example of “first gate insulating layer” in the claims) surrounds the lower portion of the Si pillar 2, and a second gate insulating layer 4b (which is an example of “second gate insulating layer” in the claims) surrounds the upper portion of the Si pillar 2. A first gate conductor layer 5a (which is an example of “first gate conductor layer” in the claims) surrounds the first gate insulating layer 4a, and a second gate conductor layer 5b (which is an example of “second gate conductor layer” in the claims) surrounds the second gate insulating layer 4b. The first gate conductor layer 5a and the second gate conductor layer 5b are isolated from each other by an insulating layer 6. Accordingly, the dynamic flash memory cell constituted by the N⁺ layers 3a and 3b, the P layer 7, the first gate insulating layer 4a, the second gate insulating layer 4b, the first gate conductor layer 5a, and the second gate conductor layer 5b is formed.

As illustrated in FIG. 1, the N⁺ layer 3a is connected to a source line SL (which is an example of “source line” in the claims), the N⁺ layer 3b is connected to a bit line BL (which is an example of “bit line” in the claims), the first gate conductor layer 5a is connected to a plate line PL (which is an example of “plate line” in the claims), and the second gate conductor layer 5b is connected to a word line WL (which is an example of “word line” in the claims). Alternatively, the first gate conductor layer 5a may be connected to the word line WL and the second gate conductor layer 5b may be connected to the plate line PL. Further, the N⁺ layer 3a may be connected to the bit line BL and the N⁺ layer 3b may be connected to the source line SL.

Desirably, the structure is such that the gate capacitance of the first gate conductor layer 5a connected to the plate line PL is larger than the gate capacitance of the second gate conductor layer 5b connected to the word line WL.

The first gate conductor layer 5a may be divided into two or more gate conductor layers along either a vertical cross section or a horizontal cross section or both a vertical cross section and a horizontal cross section and the two or more gate conductor layers may be operated synchronously or asynchronously. Similarly, the second gate conductor layer 5b may be divided into two or more gate conductor layers along either a vertical cross section or a horizontal cross section or both a vertical cross section and a horizontal cross section and the two or more gate conductor layers may be operated synchronously or asynchronously. In this case, the operations of the dynamic flash memory can also be performed.

A mechanism of an erase operation will be described with reference to FIGS. 2A to 2C. The channel region 7a between the N⁺ layers 3a and 3b is electrically isolated from the substrate 1 and functions as a floating body. FIG. 2A illustrates a state before the erase operation, in which a group of positive holes 10 generated by an impact ionization phenomenon in the previous cycle are stored in the channel region 7a. As illustrated in FIG. 2B, at the time of the erase operation, the voltage of the source line SL is set to a negative voltage V_{ERA}. Here, V_{ERA} is equal to, for example, −3 V. As a result, regardless of the value of the initial potential of the channel region 7a, the PN junction between the N⁺ layer 3a to which the source line SL is connected and which functions as the source and the channel region 7a is forward biased. As a result, the group of positive holes 10 generated by an impact ionization phenomenon in the previous cycle and stored in the channel region 7a are drawn into the N⁺ layer 3a that functions as the source, and the potential V_{FB} of the channel region 7a becomes equal to V_{FB}=V_{ERA}+Vb. Here, Vb is the built-in voltage of the PN junction and is equal to about 0.7 V. Therefore, in a case of V_{ERA}=−3 V, the potential of the channel region 7a is equal to −2.3 V. This value indicates the potential state of the channel region 7a in an erase state. Therefore, when the potential of the channel region 7a that is a floating body becomes a negative voltage, the threshold voltage for the N-channel MOS transistor of the dynamic flash memory cell increases due to a substrate bias effect. Accordingly, as illustrated in FIG. 2C, the threshold voltage of the second gate conductor layer 5b connected to the word line WL increases. This erase state of the channel region 7a corresponds to logical storage data “0”. Note that the conditions of voltages applied to the bit line BL, the source line SL, the word line WL, and the plate line PL and the potential of the floating body described above are examples for performing the erase operation, and other operation conditions based on which the erase operation can be performed may be employed.

FIGS. 3A to 3C illustrate a write operation of the dynamic flash memory cell. As illustrated in FIG. 3A, for example, 0 V is applied to the N⁺ layer 3a to which the source line SL is connected, for example, 3 V is applied to the N⁺ layer 3b to which the bit line BL is connected, for example, 2 V is applied to the first gate conductor layer 5a to which the plate line PL is connected, and, for example, 5 V is applied to the second gate conductor layer 5b to which the word line WL is connected. As a result, as illustrated in FIG. 3A, an inversion layer Ra in a ring form is formed in the channel region 7a on the inner side of the first gate conductor layer 5a to which the plate line PL is connected, and a first N-channel MOS transistor region including the first gate conductor layer 5a is operated in the saturation region. As a result, in the inversion layer Ra on the inner side of the first gate conductor layer 5a to which the plate line PL is connected, a pinch-off point P is present. In contrast, a second N-channel MOS transistor region including the second gate conductor layer 5b to which the word line WL is connected is operated in the linear region. As a result, an inversion layer Rb in which a pinch-off point is not present is formed in the channel region 7a on the entire inner side of the second gate conductor layer 5b to which the word line WL is connected.

The inversion layer Rb that is formed on the entire inner side of the second gate conductor layer 5b to which the word line WL is connected substantially functions as the drain of the first N-channel MOS transistor region including the first gate conductor layer 5a. As a result, the electric field becomes maximum in a first boundary region of the channel region 7a between the first N-channel MOS transistor region including the first gate conductor layer 5a and the second N-channel MOS transistor region including the second gate conductor layer 5b that are connected in series, and an impact ionization phenomenon occurs in this region. This region is a source-side region when viewed from the second N-channel MOS transistor region including the second gate conductor layer 5b to which the word line WL is connected, and therefore, this phenomenon is called a source-side impact ionization phenomenon. By this source-side impact ionization phenomenon, electrons flow from the N⁺ layer 3a to which the source line SL is connected toward the N⁺ layer 3b to which the bit line BL is connected. The accelerated electrons collide with lattice Si atoms, and electron-positive hole pairs are generated by the kinetic energy. Although some of the generated electrons flow into the first gate conductor layer 5a and the second gate conductor layer 5b, most of the generated electrons flow into the N⁺ layer 3b to which the bit line BL is connected. At the time of “1” writing, electron-positive hole pairs may be generated by using a gate-induced drain leakage (GIDL) current, and the floating body FB may be filled with the generated group of positive holes (see, for example, E. Yoshida, and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-697, Apr. 2006).

As illustrated in FIG. 3B, the generated group of positive holes 10 are majority carriers in the channel region 7a, with which the channel region 7a is charged to a positive bias. To the N⁺ layer 3a to which the source line SL is connected, 0 V is applied, and therefore, the channel region 7a is charged up to the built-in voltage Vb (about 0.7 V) of the PN junction between the N⁺ layer 3a to which the source line SL is connected and the channel region 7a. When the channel region 7a is charged to a positive bias, the threshold voltages for the first N-channel MOS transistor region and the second N-channel MOS transistor region decrease due to a substrate bias effect. Accordingly, as illustrated in FIG. 3C, the threshold voltage for the second N-channel MOS transistor region to which the word line WL is connected decreases. This write state of the channel region 7a is assigned to logical storage data “1”.

At the time of the write operation, electron-positive hole pairs may be generated by an impact ionization phenomenon or by a GIDL current in a second boundary region between the N⁺ layer 3a and the channel region 7a or in a third boundary region between the N⁺ layer 3b and the channel region 7a instead of the first boundary region described above, and the channel region 7a may be charged with the generated group of positive holes 10. Note that the conditions of voltages applied to the bit line BL, the source line SL, the word line WL, and the plate line PL described above are examples for performing the write operation, and other voltage conditions based on which the write operation can be performed may be employed.

A read operation of the dynamic flash memory cell will be described with reference to FIGS. 4AA to 4AC and FIGS. 4BA to 4BD. The read operation of the dynamic flash memory cell will be described with reference to FIG. 4AA to FIG. 4AC. As illustrated in FIG. 4AA, when the channel region 7a is charged up to the built-in voltage Vb (about 0.7 V), the threshold voltage decreases due to a substrate bias effect. This state is assigned to logical storage data “1”. As illustrated in FIG. 4AB, in a case where a memory block selected before writing is in an erase state “0” in advance, the floating voltage V_{FB} of the channel region 7a is equal to V_{ERA}+Vb. With a write operation, a write state “1” is stored at random. As a result, logical storage data of logical “0” and that of logical “1” are created for the word line WL. As illustrated in FIG. 4AC, the level difference between the two threshold voltages of the word line WL is used to perform reading by a sense amplifier.

The magnitude relationship between the gate capacitance of the first gate conductor layer 5a and that of the second gate conductor layer 5b at the time of the read operation of the dynamic flash memory cell and an operation related thereto will be described with reference to FIG. 4BA to FIG. 4BD. It is desirable to design the gate capacitance of the second gate conductor layer 5b to which the word line WL is connected so as to be smaller than the gate capacitance of the first gate conductor layer 5a to which the plate line PL is connected. As illustrated in FIG. 4BA, the length of the first gate conductor layer 5a, in the vertical direction, to which the plate line PL is connected is made longer than the length of the second gate conductor layer 5b, in the vertical direction, to which the word line WL is connected to make the gate capacitance of the second gate conductor layer 5b to which the word line WL is connected smaller than the gate capacitance of the first gate conductor layer 5a to which the plate line PL is connected. FIG. 4BB illustrates an equivalent circuit of one cell of the dynamic flash memory illustrated in FIG. 4BA.

FIG. 4BC illustrates a coupled capacitance relationship of the dynamic flash memory. Here, C_{WL} denotes the capacitance of the second gate conductor layer 5b, C_{PL} denotes the capacitance of the first gate conductor layer 5a, C_{BL} denotes the capacitance of the PN junction between the N⁺ layer 3b that functions as the drain and the channel region 7a, and C_{SL} denotes the capacitance of the PN junction between the N⁺ layer 3a that functions as the source and the channel region 7a. When the voltage of the word line WL changes as illustrated in FIG. 4BD, this operation affects the channel region 7a as noise. The potential change ΔV_{FB} of the channel region 7a at this time is expressed as follows.

ΔV_{FB}=C_{WL}/(C_{PL}+C_{WL}+C_{BL}+C_{SL})×V_{ReadWL} (4)

Here, V_{ReadWL} denotes a changing potential of the word line WL at the time of reading. As apparent from expression (4), when the contribution ratio of C_{WL} is made smaller relative to the total capacitance C_{PL}+C_{WL}+C_{BL}+C_{SL} of the channel region 7a, ΔV_{FB} decreases. The length of the first gate conductor layer 5a, in the vertical direction, to which the plate line PL is connected may be further made longer than the length of the second gate conductor layer 5b, in the vertical direction, to which the word line WL is connected to make ΔV_{FB} be further decreased without compromising the scale of integration of memory cells in plan view. Note that the conditions of voltages applied to the bit line BL, the source line SL, the word line WL, and the plate line PL and the potential of the floating body described above are examples for performing the read operation, and other operation conditions based on which the read operation can be performed may be employed.

The production method for the semiconductor memory device according to the first embodiment will be described with reference to FIGS. 5AA to 5AC to FIGS. 5MA to 5MC. In these figures, FIGS. 5AA, 5BA, and so on are plan views of one memory cell of the semiconductor memory device, FIGS. 5AB, 5BB, and so on are cross-sectional views cut along line X-X′ in FIGS. 5AA, 5BA, and so on respectively, and FIGS. 5AC, 5BC, and so on are cross-sectional views cut along line Y-Y′ in FIGS. 5AA, 5BA, and so on respectively. In the memory device, a large number of memory cells each of which is this memory cell are disposed in two dimensions.

As illustrated in FIGS. 5AA to 5AC, on a P-layer substrate 11 (which is an example of “substrate” in the claims), an N⁺ layer 12 (which is an example of “first impurity layer” in the claims), a first insulating layer 13 (which is an example of “first insulating layer” in the claims), a silicon-nitride (SiN) layer 14a (which is an example of “first material layer” in the claims), a second insulating layer 15 (which is an example of “second insulating layer” in the claims), a SiN layer 14b (which is an example of “second material layer” in the claims), a third insulating layer 17, and a third material layer 18 (which is an example of “third material layer” in the claims) are formed from the bottom.

Next, as illustrated in FIGS. 5BA to 5BC, the first insulating layer 13, the silicon-nitride (SiN) layer 14a, the second insulating layer 15, the SiN layer 14b, the third insulating layer 17, and the third material layer 18 are etched with a lithography method and an RIE (Reactive Ion Etching) method to make a hole 20 (which is an example of “first hole” in the claims) having a bottom portion that is on the surface or inside the N⁺ layer 12.

Next, as illustrated in FIGS. 5CA to 5CC, a Si pillar 22 (which is an example of “semiconductor pillar” in the claims) is formed in the hole 20 by using an epitaxial crystal growth method. In this case, Si is grown with an epitaxial crystal growth method such that its upper surface is above the upper surface of the third material layer 18, and subsequently, polishing is performed by CMP (Chemical Mechanical Polishing) such that the upper surface is on a level with the upper surface of the third material layer 18 to form the Si pillar 22.

Next, as illustrated in FIGS. 5DA to 5DC, a donor impurity contained in the N⁺ layer 12 is diffused in the Si pillar 22 by heat treatment to form an N⁺ layer 12a.

Next, as illustrated in FIGS. 5EA to 5EC, the SiN layers 14a and 14b are removed to make a hole 23a (which is an example of “second hole” in the claims) and a hole 23b (which is an example of “third hole” in the claims). In the actual memory device, a large number of Si pillars are disposed in two dimensions, and therefore, these Si pillars function as supporting media connected to the first insulating layer 13, the second insulating layer 15, the third insulating layer 17, and the third material layer 18. The supporting media prevent the second insulating layer 15, the third insulating layer 17, and the third material layer 18 from being bent or broken during making of the holes 23a and 23b. When dummy Si pillars are formed on the outer sides of a block region in which the Si pillars are disposed in two dimensions such that the second insulating layer 15, the third insulating layer 17, and the third material layer 18 each having one end not supported are not formed on the outer sides of the dummy Si pillars in plan view, damage caused during washing of the second insulating layer 15, the third insulating layer 17, and the third material layer 18 and etching of the SiN layers 14a and 14b can be prevented.

Next, as illustrated in FIGS. 5FA to 5FC, exposed portions of the Si pillar 22 are oxidized to form a SiO₂ layer 25a (which is an example of “first gate insulating layer” in the claims), a SiO₂ layer 25b (which is an example of “second gate insulating layer” in the claims), and a SiO₂ layer 25c.

Next, as illustrated in FIGS. 5GA to 5GC, doped poly-Si layers 26a and 26b containing a high content of donor or acceptor impurities are formed in the holes 23a and 23b. During formation of the doped poly-Si layers 26a and 26b, a doped poly-Si layer is formed on the third material layer 18 and the SiO₂ layer 25c. This doped poly-Si layer is polished with a CMP method and removed. At the same time, the SiO₂ layer 25c is removed. Subsequently, a fifth insulating layer 28 is formed on the entire top surface.

Next, as illustrated in FIGS. 5HA to 5HC, a third material layer 18a and a fifth insulating layer 28a that surround the Si pillar 22 and extend in the X-X′ line direction in plan view are formed with a photolithography method and by RIE.

Next, as illustrated in FIGS. 5IA to 5IC, the third insulating layer 17, the doped poly-Si layer 26b, the second insulating layer 15, and the doped poly-Si layer 26a are etched while the third material layer 18a and the fifth insulating layer 28a are used as etching masks to form a third insulating layer 17a, a doped poly-Si layer 26aa (which is an example of “first gate conductor layer” in the claims), a second insulating layer 15a, and a doped poly-Si layer 26ba (which is an example of “second gate conductor layer” in the claims).

Next, as illustrated in FIGS. 5JA to 5JC, a SiO₂ layer (not illustrated) is deposited over the entire structure with a CVD (Chemical Vapor Deposition) method. The SiO₂ layer is polished with a CMP method to form a SiO₂ layer 30 having an upper surface that is on a level with the upper surface of the fifth insulating layer 28a.

Next, as illustrated in FIGS. 5KA to 5KC, a portion of the third material layer 18a above the third insulating layer 17a and the fifth insulating layer 28a are removed. The upper layer of the SiO₂ layer 30 is removed to form a SiO₂ layer 30a. Accordingly, the top portion of the Si pillar 22 is exposed.

Next, as illustrated in FIGS. 5LA to 5LC, an N⁺ layer 32 (which is an example of “second impurity layer” and “third impurity layer” in the claims) is formed with a selective epitaxial crystal growth method.

Next, as illustrated in FIGS. 5MA to 5MC, a SiO₂ layer 34 is formed on the N⁺ layer 32 and the third insulating layer 17a. In a portion of the SiO₂ layer 34 above the N⁺ layer 32, a contact hole 35 is made. A metal wiring layer 36 that is connected to the N⁺ layer 32 via the contact hole 35 and that extends in the Y-Y′ line direction is formed. The N⁺ layer 12a is connected to a source line SL, the doped poly-Si layer 26aa is connected to a plate line PL, the doped poly-Si layer 26ba is connected to a word line WL, and the metal wiring layer 36 is connected to a bit line BL. Accordingly, a dynamic flash memory is formed on the P-layer substrate 11.

Note that the Si pillar 22 may be formed of another semiconductor layer. The doped poly-Si layers 26a and 26b may each be formed of a conductor layer made of metal or an alloy.

The first insulating layer 13, the second insulating layer 15, and the third insulating layer 17 may each be formed of an insulating layer, such as a SiO₂ layer, a SiN layer, or an alumina (Al₂O₃) layer, constituted by a single layer or a plurality of layers. The fifth insulating layer 28 has the role of protecting the top portion of the Si pillar 22 from RIE etching as illustrated in FIGS. 5GA to 5GC, and therefore, need not be an insulating layer but may be another material layer. The third insulating layer 17 and the third material layer 18 may be formed of one insulating layer. In this case, in the step of exposing the top portion of the Si pillar 22 in FIGS. 5KA to 5KC, the insulating layer that is left needs to have a thickness corresponding to the thickness of the third insulating layer 17a.

The N⁺ layer 12a is formed by heat treatment in the step illustrated in FIGS. 5DA to 5DC. In contrast, the N⁺ layer 12a may be formed in the step before or after formation of the Si pillar 22. In the step illustrated in FIGS. 5LA to 5LC, although an N⁺ layer is not formed in the top portion of the Si pillar 22, an N⁺ layer (which is an example of “fourth impurity layer” in the claims) may be formed in the top portion of the Si pillar 22, for example, by adding heat treatment, with an ion implantation method, or by low-temperature plasma doping. An option of forming an N⁺ layer in the top portion of the Si pillar 22 without the N⁺ layer 32 formed with a selective epitaxial crystal growth method is also possible.

In FIGS. 5EA to 5EC, although the Si pillar 22 is formed with an epitaxial crystal growth method, the Si pillar 22 may be formed with another method, such as a molecular beam crystal growth method, an ALD (Atomic Layer Deposition) method, MILC (Metal Induced Lateral Crystallization), or MSCP (Metal-assisted Solid-phase Crystallization Process).

In FIGS. 5GA to 5GC, the doped poly-Si layers 26a and 26b are formed so as to entirely surround the Si pillar 22 in plan view. In contrast, the doped poly-Si layers 26a and 26b may each be divided into two portions in plan view and formed. For example, the hole 20 is made so as to be close to a hole (not illustrated) adjacent in the X-X′ line direction. Subsequently, in FIGS. 5FA to 5FC, the SiO₂ layers 25a and 25b are formed such that the SiO₂ layers 25a and 25b are in contact with the SiO₂ layers (not illustrated) that surround the adjacent Si pillar (not illustrated). Accordingly, each of the doped poly-Si layers 26a and 26b can be isolated into portions in the Y-Y′ line direction and can be made to extend in the X-X′ line direction. In this case, even when the conductor layers connected to divided plate lines PL or divided word lines WL are driven synchronously or asynchronously, the operations of the dynamic flash memory can also be performed.

In the periphery of the N⁺ layer 12a illustrated in FIGS. 5DA to 5DC to FIGS. 5MA to 5MC, for example, an embedded conductor layer, such as a W layer, may be disposed. In the periphery of the block region of the memory cells disposed in two dimensions, a metal wiring layer connected to the N⁺ layer 12a may be disposed, and this metal wiring layer may be connected to the source line SL.

Even with a structure in which the conductivity type (polarity) of each of the N⁺ layers 3a and 3b and the P layer 7 in FIG. 1 is reversed, the operations of the dynamic flash memory can be performed. In this case, in the Si pillar 2, the majority carriers are electrons. Therefore, a group of electrons generated by an impact ionization phenomenon are stored in the channel region 7a, and a “1” state is set. The same applies to FIGS. 5AA to 5AC to FIGS. 5MA to 5MC.

This embodiment has the following features.

### Feature 1

In the write operation and in the read operation performed by the dynamic flash memory cell, the voltage of the word line WL changes. At this time, the plate line PL assumes the role of decreasing the capacitive coupling ratio between the word line WL and the channel region 7a. As a result, an effect on changes in the voltage of the channel region 7a when the voltage of the word line WL changes can be substantially suppressed. Accordingly, the difference between the threshold voltages for the MOS transistor region of the word line WL indicating logical “0” and logical “1” can be increased. This leads to an increased operation margin of the dynamic flash memory cell. In the production method for the dynamic flash memory, the doped poly-Si layer 26a connected to the plate line PL and the doped poly-Si layer 26b connected to the word line WL are defined by the thicknesses of the SiN layers 14a and 14b illustrated in FIGS. 5AA to 5AC. The thicknesses of the SiN layers 14a and 14b can be controlled with high precision on the basis of the deposition time during formation with, for example, a CVD (Chemical Vapor Deposition) method. Accordingly, a change in the voltage of the channel region 7a can be made to vary to a small degree, and this leads to an increased operation margin.

### Feature 2

As illustrated in FIGS. 5EA to 5EC and FIGS. 5FA to 5FC, when the surfaces of the exposed portions of the Si pillar 22 are oxidized in the holes 23a and 23b, the SiO₂ layers 25a and 25b that are gate insulating layers can be easily formed. This can simplify production of the dynamic flash memory. With the production method according to this embodiment, as illustrated in FIGS. 5FA to 5FC and FIGS. 5GA to 5GC, the SiO₂ layers 25a and 25b that are gate insulating layers can be formed without an increase in the thickness of the second insulating layer 15 between the doped poly-Si layers 26a and 26b. This can prevent a decrease in an ON current during a read operation. This leads to low-voltage driving for decreasing power consumption of the dynamic flash memory.

### Second Embodiment

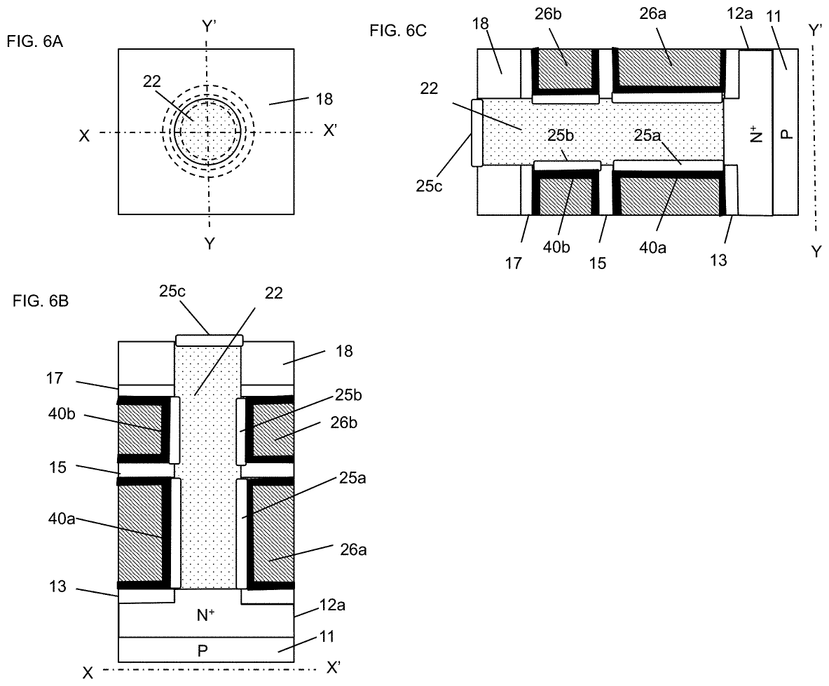

The production method for the semiconductor memory device according to a second embodiment will be described with reference to FIGS. 6A to 6C. FIG. 6A is a plan view of one memory cell of the semiconductor memory device, FIG. 6B is a cross-sectional view cut along line X-X′ in FIG. 6A, and FIG. 6C is a cross-sectional view cut along line Y-Y′ in FIG. 6A. In the memory device, a large number of memory cells each of which is this memory cell are disposed in two dimensions.

After steps similar to those illustrated in FIGS. 5AA to 5AC to FIGS. 5FA to 5FC are performed and the SiO₂ layers 25a and 25b are formed, hafnium oxide (HfO₂) layers 40a and 40b (which are an example of “third gate insulating layer” in the claims) are formed inside the holes 23a and 23b with, for example, an ALD method as illustrated in FIGS. 6A to 6C. Subsequently, the doped poly-Si layers 26a and 26b are formed. Subsequently, steps similar to those illustrated in FIGS. 5HA to 5HC to FIGS. 5MA to 5MC are performed. Accordingly, the dynamic flash memory is formed on the P-layer substrate 11. Note that as the HfO₂ layers 40a and 40b, other insulating material layers each constituted by a single layer or a plurality of layers may be used as long as the layers have the role of the gate insulating layers. The doped poly-Si layers 26a and 26b may each be formed of a conductor layer made of other metal or an alloy.

This embodiment has the following feature.

As illustrated in FIGS. 5AA to 5AC to FIGS. 5MA to 5MC, when the gate insulating layers are formed of only the SiO₂ layers 25a and 25b, the SiO₂ layers 25a and 25b are made thicker, and the effective diameter of the Si pillar 22 that functions as a channel decreases. Therefore, the volume of the channel in which a group of positive holes that function as a signal are stored decreases, and this leads to a decreased operation margin. In contrast, in this embodiment, the HfO₂ layers 40a and 40b are formed on the outer sides of the SiO₂ layers 25a and 25b, and this can reduce a decrease in the diameter of the Si pillar 22 and allow predetermined capacitances of the gate insulating layers to be formed.

### Third Embodiment

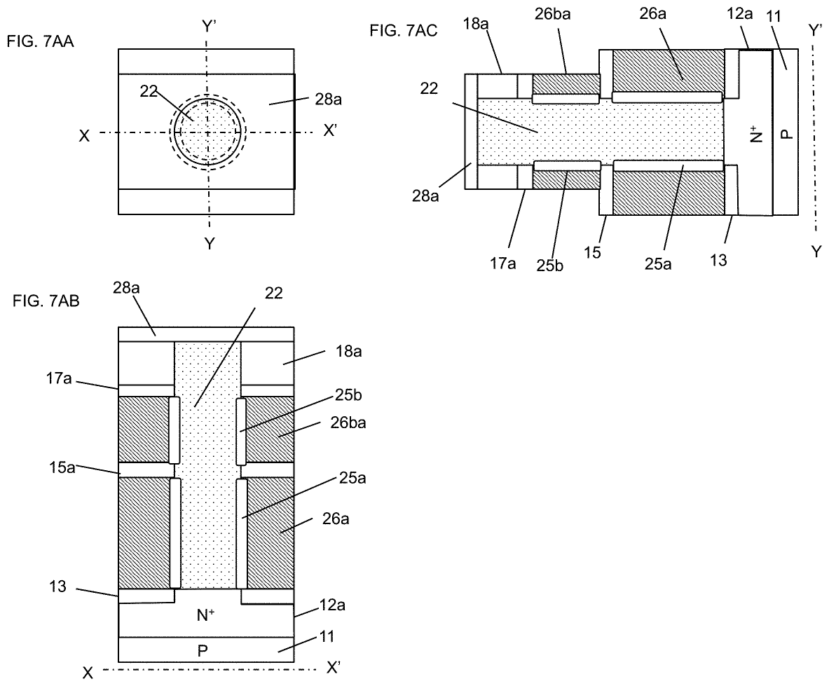

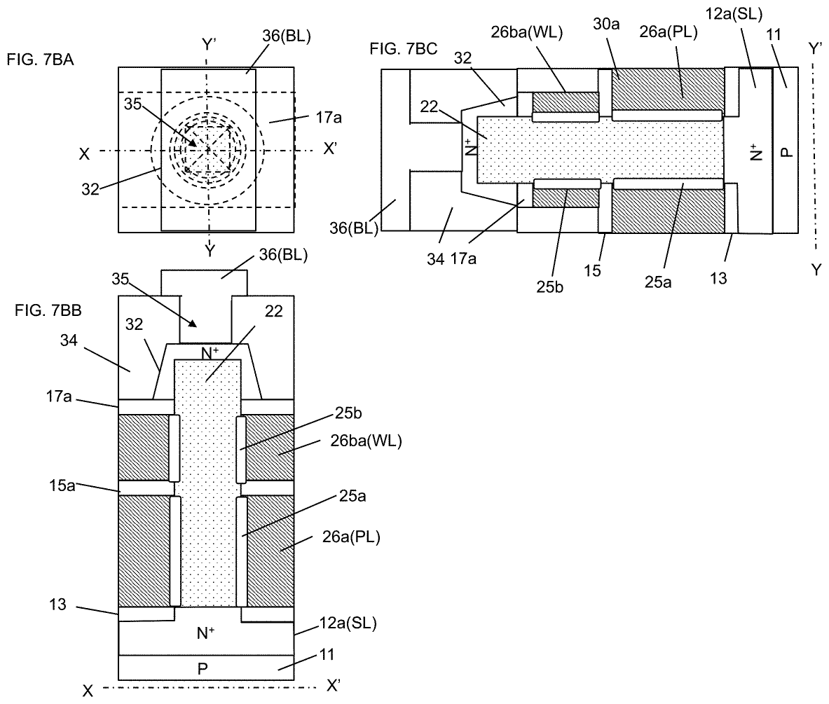

The production method for the semiconductor memory device according to a third embodiment will be described with reference to FIGS. 7AA to 7AC and FIGS. 7BA to 7BC. FIGS. 7AA and 7BA are plan views of one memory cell of the semiconductor memory device, FIGS. 7AB and 7BB are cross-sectional views cut along line X-X′ in FIGS. 7AA and 7BA respectively, and FIGS. 7AC and 7BC are cross-sectional views cut along line Y-Y′ in FIGS. 7AA and 7BA respectively. In the memory device, a large number of memory cells each of which is this memory cell are disposed in two dimensions and formed in the memory cell region.

After steps similar to those illustrated in FIGS. 5AA to 5AC to FIGS. 5HA to 5HC are performed, the third insulating layer 17 and the doped poly-Si layer 26b are etched while the third material layer 18a and the fifth insulating layer 28a are used as etching masks to form the third insulating layer 17a and the doped poly-Si layer 26ba (which is an example of “second gate conductor layer” in the claims) as illustrated in FIGS. 7AA to 7AC. In this case, the doped poly-Si layer 26a is not etched but is left and formed so as to be connected with the adjacent Si pillar (not illustrated).

Next, steps similar to those illustrated in FIGS. 5JA to 5JC to FIGS. 5MA to 5MC are performed. Accordingly, although the doped poly-Si layer 26aa connected to the plate line PL has a shape the same as that of the doped poly-Si layer 26ba connected to the word line WL in plan view in FIGS. 5MA to 5MC in the first embodiment, the doped poly-Si layer 26a connected to the plate line PL is not etched but is left and formed so as to be connected to the adjacent Si pillar (not illustrated) as illustrated in FIGS. 7BA to 7BC in this embodiment. Accordingly, the dynamic flash memory is formed on the P-layer substrate 11.

This embodiment has the following feature.

In this embodiment, etching processing of the doped poly-Si layer 26a connected to the plate line PL is not necessary in the memory cell region. This can facilitate production of the dynamic flash memory.

### Other Embodiments

In FIG. 1, to make the gate capacitance of the first gate conductor layer 5a connected to the plate line PL larger than the gate capacitance of the second gate conductor layer 5b to which the word line WL is connected, the gate length of the first gate conductor layer 5a is made longer than the gate length of the second gate conductor layer 5b. Alternatively, instead of making the gate length of the first gate conductor layer 5a longer than the gate length of the second gate conductor layer 5b, the thickness of the gate insulating film of the first gate insulating layer 4a may be made thinner than the thickness of the gate insulating film of the second gate insulating layer 4b. Alternatively, the dielectric constant of the first gate insulating layer 4a may be made higher than the dielectric constant of the second gate insulating layer 4b. The gate capacitance of the first gate conductor layer 5a may be made larger than the gate capacitance of the second gate conductor layer 5b, by a combination of any of the lengths of the first gate conductor layer 5a and the second gate conductor layer 5b and the thicknesses and dielectric constants of the first gate insulating layer 4a and the second gate insulating layer 4b. The same applies to other embodiments.

Note that in FIG. 1, the length of the first gate conductor layer 5a, in the vertical direction, to which the plate line PL is connected is made further longer than the length of the second gate conductor layer 5b, in the vertical direction, to which the word line WL is connected to attain C_{PL}>C_{WL} However, when only the plate line PL is added, the capacitive coupling ratio (C_{WL}/C_{PL}+C_{WL}+C_{BL}+C_{SL})) of the word line WL to the channel region 7a decreases. As a result, the potential change ΔV_{FB} of the channel region 7a that is a floating body decreases. The same applies to other embodiments.

As the voltage of the plate line PL described in the embodiment, for example, a fixed voltage may be applied regardless of the operation mode. As the voltage of the plate line PL, for example, 0 V may be applied only at the time of erasing. As the voltage of the plate line PL, a fixed voltage or a voltage changing over time may be applied as long as the voltage satisfies the conditions based on which the operations of the dynamic flash memory can be performed.

Although the Si pillar 2 has a round shape in plan view in FIG. 1, the Si pillar 2 may have, for example, an elliptic shape or a shape elongated in one direction instead of a round shape. The same applies to other embodiments.

Although a negative bias is applied to the source line SL at the time of the erase operation to discharge the group of positive holes in the channel region 7a that is the floating body FB as described in the embodiment, the erase operation may be performed on the basis of other voltage conditions.

In FIG. 1, an N-type impurity layer or a P-type impurity layer having a different acceptor impurity concentration may be disposed between the N⁺ layer 3a and the P layer 7. An N-type impurity layer or a P-type impurity layer may be disposed between the N⁺ layer 3b and the P layer 7. The same applies to other embodiments.

The N⁺ layers 3a and 3b in FIG. 1 may be formed of Si or other semiconductor material layers containing a donor impurity. The N⁺ layer 3a and the N⁺ layer 3b may be formed of different semiconductor material layers. Conductor layers made of, for example, metal or silicide that partially or entirely surround the N⁺ layers 3a and 3b may be disposed. The same applies to other embodiments.

The Si pillars 22, each of which is the Si pillar 22 illustrated in FIGS. 5CA to 5CC to FIGS. 5MA to 5MC, may be arranged in two dimensions in a square lattice or in a diagonal lattice. When the Si pillars are disposed in a diagonal lattice, the Si pillars connected to one word line may be disposed in a honeycomb pattern or in a zigzag pattern or a serrated pattern in which each segment is constituted by a plurality of Si pillars. In FIGS. 5IA to 5IC, the third insulating layer 17, the doped poly-Si layer 26b, the second insulating layer 15, and the doped poly-Si layer 26a are etched while the third material layer 18a and the fifth insulating layer 28a are used as etching masks in plan view to form the third insulating layer 17a, the doped poly-Si layer 26aa, the second insulating layer 15a, and the doped poly-Si layer 26ba. This case is an example where the third insulating layer 17a, the doped poly-Si layer 26aa, the second insulating layer 15a, and the doped poly-Si layer 26ba are formed so as to be isolated from dynamic flash memory cells adjacent in the Y-Y′ line direction in plan view. In contrast, the third insulating layer 17a, the doped poly-Si layer 26aa, the second insulating layer 15a, and the doped poly-Si layer 26ba may be formed so as to be connected to dynamic flash memory cells adjacent in the Y-Y′ line direction in plan view. The same applies to other embodiments.

Instead of the P-layer substrate 11 in FIGS. 5AA to 5AC to FIGS. 5MA to 5MC, SOI or a multilayer well may be used. The same applies to other embodiments.

Although an example where each of the first gate conductor layer 5a and the second gate conductor layer 5b is formed of one conductor material layer is illustrated in FIG. 1, each of the first gate conductor layer 5a and the second gate conductor layer 5b may be formed of a plurality conductor layers in the vertical direction or in the horizontal direction. When each of the first gate conductor layer 5a and the second gate conductor layer 5b is formed of a plurality conductor material layers, an insulating layer may be disposed between the conductor material layers. When, for example, the conductor material layers are made to have the same thicknesses, embedding of the doped poly-Si layers in FIGS. 5GA to 5GC can be made uniform, which is an advantage. The same applies to other embodiments.

When dynamic flash memory cells, each of which is the dynamic flash memory cell illustrated in FIG. 1, are stacked in a plurality of stages in the vertical direction, in plan view, the plate line conductor layer in each stage extends in a direction the same as the direction in which the first gate conductor layer extends, the word line conductor layer in each stage extends in a direction the same as the direction in which the second gate conductor layer extends, and the word line conductor layer and the plate line conductor layer in each stage extend in the same direction. The same applies to other embodiments.

Various embodiments and modifications can be made to the present invention without departing from the spirit and scope of the present invention in a broad sense. The above-described embodiments are intended to explain examples of the present invention and are not intended to limit the scope of the present invention. Any of the above-described embodiments and modifications can be combined. Further, the above-described embodiments from which some of the configuration requirements are removed as needed are also within the scope of the technical spirit of the present invention.

With the production method for the semiconductor memory device according to the present invention, a high-density and high-performance dynamic flash memory can be obtained.

What is claimed is:

1. A production method for a semiconductor memory device, the semiconductor memory device performing a data retention operation of retaining, inside a semiconductor pillar, a group of positive holes or a group of electrons that are majority carriers in the semiconductor pillar and that are generated by an impact ionization phenomenon or a gate-induced drain leakage current, by controlling voltages applied to a first gate conductor layer, a second gate conductor layer, a first impurity layer, and a second impurity layer, and a data erase operation of discharging, from inside the semiconductor pillar, the group of positive holes or the group of electrons that are majority carriers in the semiconductor pillar by controlling the voltages applied to the first gate conductor layer, the second gate conductor layer, the first impurity layer, and the second impurity layer, the production method comprising:
stacking the first impurity layer, a first insulating layer, a first material layer, a second insulating layer, a second material layer, and a third material layer on a substrate from a bottom in a vertical direction;
making a first hole that has a bottom portion on a surface or inside the first impurity layer and that extends through the first insulating layer, the first material layer, the second insulating layer, the second material layer, and the third material layer;
forming the semiconductor pillar by filling the first hole;
making a second hole by removing the first material layer, and making a third hole by removing the second material layer;
forming a first gate insulating layer by oxidizing a surface layer of the semiconductor pillar exposed in the second hole, and forming a second gate insulating layer by oxidizing a surface layer of the semiconductor pillar exposed in the third hole;
forming the first gate conductor layer by filling the second hole so as to cover the first gate insulating layer, and forming the second gate conductor layer by filling the third hole so as to cover the second gate insulating layer; and
forming the second impurity layer connected to a top portion of the semiconductor pillar.

2. The production method for a semiconductor memory device according to claim 1, the production method further comprising:
forming one of the first impurity layer or the second impurity layer so as to be connected to a source line, and forming the other of the first impurity layer or the second impurity layer so as to be connected to a bit line.

3. The production method for a semiconductor memory device according to claim 1, the production method further comprising:
forming one of the first gate conductor layer or the second gate conductor layer so as to be connected to a word line, and forming the other of the first gate conductor layer or the second gate conductor layer so as to be connected to a plate line.

4. The production method for a semiconductor memory device according to claim 1, the production method further comprising:
exposing the top portion of the semiconductor pillar by removing an upper portion of the third material layer, the third material layer being formed of two material layers including a lower layer that is an insulating layer, or by etching an upper portion of the third material layer, the third material layer being formed of an insulating material layer; and
forming a third impurity layer so as to cover the exposed top portion of the semiconductor pillar, wherein
the third impurity layer functions as the second impurity layer.

5. The production method for a semiconductor memory device according to claim 3, the production method further comprising:
forming a fourth impurity layer in the top portion of the semiconductor pillar, wherein
the third impurity layer and the fourth impurity layer form the second impurity layer.

6. The production method for a semiconductor memory device according to claim 1, wherein
the first gate insulating layer and the second gate insulating layer are formed, and subsequently, a third gate insulating layer is formed on an inner wall of the second hole and on an inner wall of the third hole so as to cover the first gate insulating layer and the second gate insulating layer respectively.

7. The production method for a semiconductor memory device according to claim 1, wherein
the third material layer includes at least one insulating layer.

8. The production method for a semiconductor memory device according to claim 1, the production method further comprising:
forming dummy semiconductor pillars in an outermost area of a block region, in plan view, in which semiconductor pillars each of which is the semiconductor pillar are disposed in two dimensions; and
etching and removing a portion of the first insulating layer, a portion of the first material layer, a portion of the second insulating layer, a portion of the second material layer, and a portion of the third material layer, the portions being outside the block region in plan view, prior to the making of the second hole by removing the first material layer and the making of the third hole by removing the second material layer.

9. The production method for a semiconductor memory device according to claim 1, the production method further comprising:
isolating one of the first gate conductor layer or the second gate conductor layer into a plurality of gate conductor layers in the vertical direction, or isolating each of the first gate conductor layer and the second gate conductor layer into a plurality gate conductor layers in the vertical direction.
